(19) United States
(12) Patent Application Publication
(10) Pub. No.: US 2026/0247757 A1
(43) Pub. Date: Aug. 20, 2026

(54) LIGHT EMITTING DEVICE AND LIGHT EMITTING SYSTEM INCLUDING THE SAME

(71) Applicant: SEOUL VIOSYS CO., LTD., Ansan-si (KR)

(72) Inventors: Jina LEE, Ansan-si (KR); ChangYoun KIM, Ansan-si (KR)

(73) Assignee: SEOUL VIOSYS CO., LTD., Ansan-si (KR)

(21) Appl. No.: 19/535,315

(22) Filed: Feb. 10, 2026

Related U.S. Application Data
(60) Provisional application No. 63/760,319, filed on Feb. 19, 2025.

(51) Int. Cl. H10H 20/831; H10W 90/00

(52) U.S. Cl. CPC H10H 20/831; H10W 90/724; H10W 90/756

(57) ABSTRACT

A light emitting device includes: a substrate; a light emitter disposed on the substrate to generate light; a molding layer disposed on the substrate to cover the light emitter; and a plurality of wavelength converting particles disposed in the molding layer. The molding layer includes: a first molding region disposed directly above the light emitter; and a second molding region disposed laterally adjacent to the light emitter. A density of the wavelength converting particles in the first molding region is greater than a density of the wavelength converting particles in the second molding region.

### TECHNICAL FIELD

The present disclosure relates to a light emitting device and a light emitting system including the same.

### BACKGROUND

Recently, light emitting diodes (LEDs) have been widely used. A light emitting diode utilizes properties of a compound semiconductor to convert an electrical signal into a form of light, such as infrared, visible, or ultraviolet light.

As the luminous efficiency of light emitting diodes is increased, light emitters are being applied in various fields including display devices, lighting fixtures, and vehicles.

Recently, the need for a light emitting device emitting light for displaying various information has increased.

### SUMMARY

Embodiments of the present disclosure provide a light emitting device for forming a stereoscopic image, such as a figure, character, or video, and a light emitting system including the same.

Furthermore, embodiments of the present disclosure provide a light emitting device with improved light extraction efficiency and a light emitting system including the same.

Furthermore, embodiments of the present disclosure provide a light emitting device with an improved contrast ratio and a light emitting system including the same.

Furthermore, embodiments of the present disclosure provide a light emitting device with improved reliability and a light emitting system including the same.

Furthermore, embodiments of the present disclosure provide a light emitting device with reduced image distortion and a light emitting system including the same.

Furthermore, embodiments of the present disclosure provide a light emitting device with improved color accuracy and a light emitting system including the same.

Furthermore, embodiments of the present disclosure provide a light emitting device with improved surface quality and a light emitting system including the same.

In accordance with a first embodiment of the present disclosure, there is provided a light emitting device, including: a substrate; a light emitter disposed on the substrate to generate light; a molding layer disposed on the substrate to cover the light emitter; and a plurality of wavelength converting particles disposed in the molding layer, wherein the molding layer includes: a first molding region disposed directly above the light emitter; and a second molding region disposed laterally adjacent to the light emitter, and wherein a density of the wavelength converting particles in the first molding region is greater than a density of the wavelength converting particles in the second molding region.

Further, the first molding region may be a region from a top surface of the light emitter to a top surface of the molding layer.

Further, the light emitter and the first molding region may be formed in plurality and be arranged spaced apart from each other in one direction, and the second molding region may be disposed between the plurality of first molding regions.

Further, the second molding region may be disposed such that a surface of the molding layer is disposed on a top surface of the second molding region, and the first molding region and the second molding region may have the same thickness.

Further, when a cross-section is formed by cutting the molding layer in a direction passing through the plurality of light emitters arranged in the one direction and perpendicular to the substrate, the density of the wavelength converting particles may be calculated by a number of the wavelength converting particles disposed on the cross-section or an area of the wavelength converting particles on the cross-section.

Further, the first molding region may be disposed to be in contact with a top surface of the light emitter and a top surface of the molding layer, and a thickness of the second molding region may be greater than a thickness of the first molding region.

Further, the second molding region may be disposed such that a surface of the molding layer is disposed on a top surface of the second molding region, the molding layer may further include a third molding region disposed below the second molding region, and a density of the wavelength converting particles in the third molding region is less than the density of the wavelength converting particles in the first molding region.

Further, a thickness of the third molding region may be the same as a thickness of the first molding region.

Further, the light emitting device may further include: an electrode pad disposed between the substrate and the light emitter, electrically connected to the light emitter, and covered by the molding layer, an outer side of the electrode pad is disposed outward of a side surface of the light emitter, the molding layer includes a fourth molding region enclosed by a virtual line extending from the outer side of the electrode pad to an edge of a top surface of the light emitter, a side surface of the light emitter, and a top surface of the electrode pad, and a density of the wavelength converting particles in the fourth molding region is greater than the density of the wavelength converting particles in the second molding region.

In accordance with a second embodiment of the present disclosure, there is provided a light emitting device, including: a substrate; a plurality of light emitters disposed on the substrate to generate light; a molding layer disposed on the substrate to cover the plurality of light emitters; and a plurality of wavelength converting particles disposed in the molding layer, wherein the molding layer includes: a first molding layer covering the plurality of light emitters and transmitting light generated from the plurality of light emitters; and a second molding layer stacked on the first molding layer and having a lower light transmittance than the first molding layer, and wherein the wavelength converting particles are disposed in at least one of the first molding layer and the second molding layer.

Further, the molding layer may include: a first molding region disposed directly above the plurality of light emitters; and a second molding region disposed laterally adjacent to the plurality of light emitters, a portion of the first molding layer and a portion of the second molding layer may be disposed in the first molding region, another portion of the first molding layer and another portion of the second molding layer may be disposed in the second molding region, and a density of the wavelength converting particles in the first molding region may be greater than a density of the wavelength converting particles in the second molding region.

Further, the first molding layer included in the first molding region may be formed to be convex upward.

Further, a thickness of the portion of the second molding layer in the first molding region may be smaller than a thickness of the another portion of the second molding layer in the second molding region.

Further, a light transmittance in the second molding layer disposed in the first molding region may be greater than a light transmittance in the second molding layer disposed in the second molding region.

Further, a thickness of the first molding layer may be greater than a thickness of the second molding layer.

In accordance with a third embodiment of the present disclosure, there is provided a light emitting device, including: a substrate; a light emitter disposed on the substrate to generate light; a reflective layer disposed on the substrate and positioned laterally of the light emitter to reflect light toward the light emitter; a molding layer covering an upper side of the reflective layer and the light emitter; and a plurality of wavelength converting particles disposed in the molding layer, wherein the molding layer includes: a first molding region disposed directly above the light emitter; and a second molding region disposed directly above the reflective layer, and wherein a density of the wavelength converting particles in the first molding region is greater than a density of the wavelength converting particles in the second molding region.

Further, the reflective layer may include: a reflective region disposed laterally of the light emitter to reflect light toward the light emitter; and a light absorbing layer covering the reflective region and disposed below the molding layer to absorb light.

Further, a thickness of the reflective region may be greater than a thickness of the light absorbing layer.

Further, a reflectance of the reflective region may be greater than a reflectance of the molding layer.

Further, the light emitter may include a plurality of light emitters, and a bottom surface of the molding layer may be bent downward between the plurality of light emitters so as to be disposed lower than an upper end of the plurality of light emitters.

In an embodiment of the present disclosure, since a density of the wavelength converting particles in a region directly over the light emitter is greater than a density thereof in other regions of the molding layer, a wavelength of light generated from the light emitter may be efficiently converted.

Furthermore, in an embodiment of the present disclosure, since the density of the wavelength converting particles in the region directly over the light emitter may be formed to be greater than the density thereof in other regions of the molding layer, a distinct contrast ratio and contrast are achieved.

Furthermore, in an embodiment of the present disclosure, since a light transmittance of a molding layer disposed directly above a plurality of light emitters may be formed to be high, and a light transmittance of a molding layer disposed between the plurality of light emitters may be formed to be low, a distinct contrast ratio and contrast are achieved.

Furthermore, in embodiments of the present disclosure, since a reflective layer may reduce optical interference between a plurality of light emitters, a distinct contrast ratio and contrast are achieved.

Furthermore, in embodiments of the present disclosure, since the reflective layer may reflect light toward the light emitter, light extraction efficiency may be increased.

Furthermore, in embodiments of the present disclosure, since light may be absorbed, mixing of light between adjacent light emitters may be prevented, and color distinction between the light emitters may become more distinct.

### BRIEF DESCRIPTION OF THE DRAWINGS

FIG. 1 is a perspective view illustrating a first example of a light emitting system including a light emitting device according to a first embodiment of the present disclosure.

FIG. 2 is a perspective view illustrating a second example of the light emitting system including the light emitting device according to the first embodiment of the present disclosure.

FIG. 3 is a diagram illustrating the light emitting device according to the first embodiment of the present disclosure.

FIG. 4 is a diagram illustrating a light emitting device according to a second embodiment of the present disclosure.

FIG. 5 is a diagram illustrating a light emitting device according to a third embodiment of the present disclosure.

FIG. 6 is a diagram illustrating a light emitting device according to a fourth embodiment of the present disclosure.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the D2R-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting device 10 and a light emitting system 1 including the same according to a first embodiment of the present disclosure will be described.

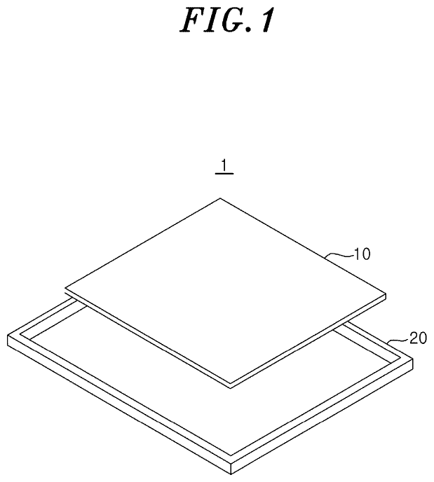

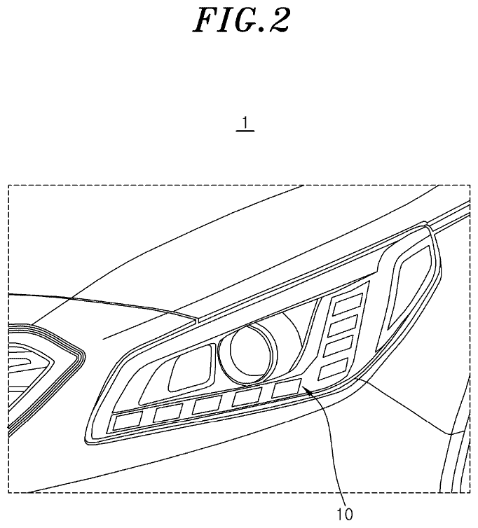

The light emitting system 1 may be the display device of FIG. 1 or the vehicle lamp of FIG. 2, but is not limited thereto. The light emitting system 1 may include a light emitting device 10 and a frame 20. Furthermore, the light emitting system 1 may include a plurality of light emitting devices 10 depending on the size of the light emitting system 1.

The light emitting system 1 of FIG. 1 is a display device and may include one or more light emitting devices 10 including a plurality of light emitters 200, to be described later. The light emitting system 1 may display information and may output various visual contents.

The frame 20 may be disposed on an outer side of the light emitting system 1. An electrical wiring may be added to a region of the frame 20, so that the light emitting system 1 is electrically connected to an external power source and an operation of the light emitting system 1 may be controlled according to an electrical signal. Furthermore, the light emitting system 1 may be controlled according to an external signal and thus may be driven in various ways.

The frame 20 may perform a role of reinforcing the strength of the light emitting system 1 and may be made of a material having a higher strength than a substrate 100 of the light emitting device 10, which will be described later. Such a frame 20 may also be utilized as a structural support connecting different light emitting devices 10. Various materials may be used for the frame 20 depending on mechanical strength, processability, and the like. For example, the frame 20 may include a metallic material such as aluminum, stainless steel, or copper. In another example, the frame 20 may include a polymer material such as polycarbonate, acrylic, polyamide, or ABS, or carbon fiber reinforced plastic, glass fiber reinforced plastic, or ceramic.

Furthermore, the frame 20 may be manufactured in a shape surrounding the light emitting device 10 to reinforce the strength of the light emitting system 1, but is not limited thereto. The frame 20 may also be disposed on one surface of the light emitting device 10 to reduce an area of the light emitting system 1.

Furthermore, the light emitting system 1 may further include a diffusion plate and a plurality of optical sheets. A display panel may be disposed on one surface of the optical sheet. The display panel is not particularly limited. For example, the display panel may be a liquid crystal display panel including a liquid crystal layer. Furthermore, a gate driving PCB for supplying a driving signal to a gate line and a data driving PCB for supplying a driving signal to a data line may be provided at an edge of the display panel.

The light emitting system 1 may constitute not only a display device but also a vehicle light source. The light emitting system 1 of the present disclosure may improve chromatic aberration of a vehicle light source by varying the density of wavelength converting particles 400 for each region, to be described later. Particularly in a light emitting system 1 requiring zonal driving, such as a smart headlamp, a clear projection image may be implemented by reducing crosstalk between projection areas.

Furthermore, the light emitting device 10 may display characters, symbols, images, or videos. Furthermore, the light emitting device 10 may be mounted in a vehicle. In other words, the light emitting device 10 may be included in a taillight, a headlight, a grill lamp, a rear lamp, a tail lamp, an interior light, and the like. Furthermore, the light emitting device 10 has a distinct contrast ratio by reducing optical interference between the plurality of light emitters 200 (light emitters) and minimizing interference between driving regions, thereby enabling the implementation of a high-quality display device with clear contrast.

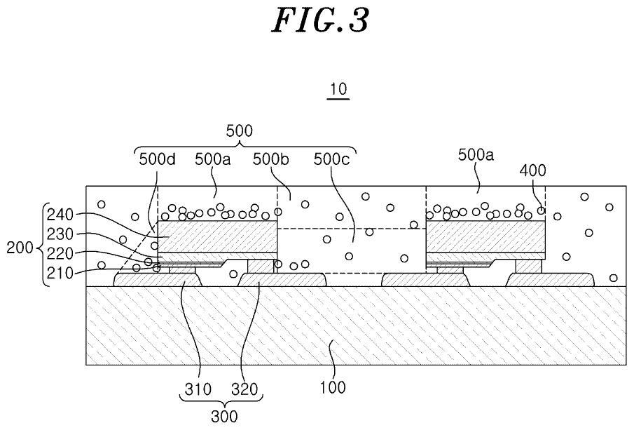

Referring further to FIG. 3, the light emitting device 10 may include a substrate 100, a light emitter 200, an electrode pad 300, wavelength converting particles 400, and a molding layer 500.

A plurality of light emitters 200, electrode pads 300, and a molding layer 500 may be disposed on the substrate 100. For example, the substrate 100 may be a printed circuit board (PCB) on which an electric circuit is printed. Furthermore, the substrate 100 may be a thin-film transistor (TFT) backplane. The substrate 100 may include an alloy composed of at least one of Cu, Zn, Au, Ni, Al, Mg, Cd, Be, W, Mo, Si, Ag, and Fe, having thermal conductivity, and accordingly, conductivity of heat and electricity may be increased. However, this is merely an example, and the substrate 100 may include at least one insulating material such as FR1, CEM-1, FR-4, PMMA, PCT, and PPA, and through this, short circuits between respective circuits may be prevented. Here, FR1 is a material in which a copper foil and a laminate paper are stacked, and CEM-1 is a material in which a copper foil, a glass fiber fabric, a laminate paper, and a glass fiber fabric are sequentially stacked. In addition, FR-4 is a material in which a copper foil and a glass fiber fabric or a glass fiber fabric are stacked. Furthermore, the substrate 100 may include a ceramic such as alumina (Al₂O₃), aluminum nitride (AlN), or Zirconia Toughened Alumina (ZTA).

The light emitter 200 may generate light. A plurality of light emitters 200 may be formed and may be disposed on the substrate 100 to be spaced apart from each other in one direction. The plurality of light emitters 200 may be electrically connected to an electrical circuit of the substrate 100 and may generate light by being supplied with electricity from an external source through the electrical circuit. For example, the plurality of light emitters 200 may be arranged in N rows and M columns and may each generate light. The number of rows N and the number of columns M of the plurality of light emitters 200 may be the same or different. The plurality of light emitters 200 may generate light of different colors or may generate light of the same color. For example, each of the plurality of light emitters 200 may generate blue, green, red, white light, UV light, or the like.

Each of the plurality of light emitters 200 may include a first conductive type semiconductor layer 210, an active layer 220, a second conductive type semiconductor layer 230, and a transmissive layer 240.

The first conductive type semiconductor layer 210 is a semiconductor layer having a polarity opposite to that of the second conductive type semiconductor layer 230. The first conductive type semiconductor layer 210 may include a p-type impurity (for example, Mg, Sr, Ba). In this case, the first conductive type semiconductor layer 210 may be a p-type semiconductor layer. However, this is merely an example, and the first conductive type semiconductor layer 210 may include an n-type impurity.

The active layer 220 may be stacked on the first conductive type semiconductor layer 210. In other words, the active layer 220 may be located between the first conductive type semiconductor layer 210 and the second conductive type semiconductor layer 230. Furthermore, the first conductive type semiconductor layer 210 and the active layer 220 may form a mesa. Furthermore, the active layer 220 may be disposed above a center of the light emitter 200. Due to the active layer 220, a length of the first conductive type semiconductor layer 210 in a vertical direction may be formed to be greater than a length of the second conductive type semiconductor layer 230 in the vertical direction.

The second conductive type semiconductor layer 230 may be stacked on the active layer 220. The second conductive type semiconductor layer 230 may include an n-type impurity (for example, Si, Ge, Sn), and in this case, the second conductive type semiconductor layer 230 may be an n-type semiconductor layer. However, this is merely an example, and the second conductive type semiconductor layer 230 may include a p-type impurity. Light generated in the active layer 220 may pass through the second conductive type semiconductor layer 230 and be emitted to the outside.

The transmissive layer 240 may be stacked on the second conductive type semiconductor layer 230. The transmissive layer 240 may be an insulating or conductive substrate, and may also be an insulating or conductive substrate bonded by bonding. Furthermore, the transmissive layer 240 may be an insulating or conductive substrate for growing the first conductive type semiconductor layer 210, the active layer 220, and the second conductive type semiconductor layer 230. For example, the transmissive layer 240 may include at least one of a silicon carbide substrate, a silicon substrate, a gallium nitride substrate, an aluminum nitride substrate, a sapphire substrate, and a patterned sapphire substrate, such as an Insulation Patterned Sapphire Substrate (IPSS).

The electrode pads 300 may be disposed between the substrate 100 and the plurality of light emitters 200 and may be electrically connected to the light emitters 200, respectively. An outer side of the electrode pad 300 may be disposed further outward than a side surface of the light emitter 200 when viewed from above. The electrode pad 300 may include a first electrode pad 310 and a second electrode pad 320.

The first electrode pad 310 is disposed on the substrate and may be electrically connected to the first conductive type semiconductor layer 210. The outer side of the first electrode pad 310 may be disposed more to the outside than one side surface of the light emitter 200 when viewed from above.

The second electrode pad 320 is disposed on the substrate to be spaced apart from the first electrode pad 310 in one direction and may be electrically connected to the second conductive type semiconductor layer 230. An outer side of the first electrode pad 310 may be disposed more to the outside than another side surface opposite to the one side surface of the light emitter 200 when viewed from above.

The wavelength converting particles 400 may absorb light emitted from the light emitter 200 and be excited to emit light of a different wavelength. The wavelength converting particles 400 may include phosphor particles, quantum dots, organic dyes, or the like. The wavelength converting particles 400 may be disposed in the molding layer 500. For example, the wavelength converting particles 400 may be a YAG ((Y, Gd)₃(Al, Ga)₅O₁₂: Ce³⁺) based phosphor, a TAG ((Tb, Gd)₃(Al, Ga)₅O₁₂: Ce³⁺) based phosphor, (Ba, Sr, Ca) ₂SiO₄: Eu²⁺, (Ba, Sr, Ca)₃SiO₅: Eu²⁺, (Ba, Sr, Ca)MgSi₂O₆: Eu²⁺, Mn²⁺, (Ba, Sr, Ca)₃MgSi₂O₈: Eu²+, Mn²⁺, and (Ba, Sr, Ca)MgSiO₄: Eu²⁺, Mn²⁺, or a Fluoride-based phosphor represented by A₂MF₆: Mn⁴⁺, where A may be Li, Na, K, Ba, Rb, Cs, Mg, Ca, Se, or Zn, and M may be at least one selected from the group consisting of Ti, Si, Zr, Sn, or Ge. Such wavelength converting particles 400 may emit green, yellow, blue, red, white, or other excitation light. The excitation light may have a peak wavelength in a wavelength band longer than the peak wavelength of the light emitted from the light emitter 200. Furthermore, the excitation light may have a wider full width at half maximum than the wavelength emitted from the light emitter 200. Accordingly, light of a wide color gamut may be reproduced.

The molding layer 500 may be disposed on the substrate 100 to cover the plurality of light emitters 200 and the electrode pads 300. The molding layer 500 may be made of an organic material such as a silicone resin like methyl silicone or phenyl silicone, as well as Fluoropolymer, Epoxy, Polyphthalamide (PPA), Polybutylene terephthalate (PBT), Polycarbonate (PC), polyimide (PI), polyethylene terephthalate (PET), polyethylene naphthalate (PEN), or fluoropolymer. Furthermore, the molding layer 500 may also be made of an inorganic-based transparent material such as ceramic or glass.

Furthermore, the molding layer 500 may be made from various thermosetting resins, such as epoxy resin, polyimide, phenolic resin, or silicone, including materials in the A-stage, B-stage, or C-stage of curing. The A-stage is a state where the resin is liquid and fully fluid, suitable for initial mixing and molding operations. The B-stage is a partially cured state, where the material has some strength but may still be further molded or laminated. The C-stage is a fully cured state, where no further molding is possible, but the C-stage provides very high mechanical strength and stability. Accordingly, the molding layer 500 may prevent external impact on the product, enhance mechanical strength, and increase environmental reliability, while also contributing to reducing process difficulty.

Furthermore, the wavelength converting particles 400 may be disposed in the molding layer 500. A density of the wavelength converting particles 400 disposed in the molding layer 500 may be calculated by the number of wavelength converting particles 400 disposed on a cross-section or the area of the wavelength converting particles 400 on the cross-section, when the cross-section is formed by cutting the molding layer 500 in a direction passing through a center of each of the plurality of light emitters 200 arranged in one direction and perpendicular to the substrate 100. The molding layer 500 may include a first molding region 500a, a second molding region 500b, a third molding region 500c, and a fourth molding region 500d.

The first molding region 500a may be a region disposed directly above each of the plurality of light emitters 200. The plurality of wavelength converting particles 400 may be disposed in the first molding region 500a. A bottom surface of the first molding region 500a is a bottom surface of the molding layer 500 located on a top surface of the light emitter 200, and a top surface of the first molding region 500a may be a top surface of the molding layer 500. In other words, the first molding region 500a may be a region from the top surface of the light emitter 200 to the top surface of the molding layer 500. The density of the wavelength converting particles 400 in this first molding region 500a is greater than the density of the wavelength converting particles 400 in the second molding region 500b, the third molding region 500c, and the fourth molding region 500d. The density of the wavelength converting particles 400 of the first molding region 500a may be calculated by the number of wavelength converting particles 400 disposed on a first cross-section or the area of the wavelength converting particles 400 relative to a total area of the first cross-section, when the first cross-section of the first molding region 500a is formed by cutting the first molding region 500a in a direction passing through cross-sections of at least two of the plurality of light emitters 200 arranged in one direction and perpendicular to the substrate 100. The density of the wavelength converting particles 400 of the first molding region 500a may be 20% to 30% of the total area of the first cross-section.

The wavelength conversion particles 400 disposed in the first molding region 500a may be arranged closer to the top surface of the light emitter 200 than to the top surface of the molding layer 500.

The second molding region 500b may be disposed in a side region between the plurality of light emitters 200. Furthermore, the second molding region 500b may be disposed between the plurality of first molding regions 500a. A thickness of the second molding region 500b may be formed to be different from a thickness of the first molding region 500a. In other words, the thickness of the second molding region 500b may be formed to be greater than the thickness of the first molding region 500a. Furthermore, a bottom surface of the second molding region 500b may be disposed lower than a bottom surface of the transmissive layer 240 of the light emitter 200, but is not limited thereto. In another embodiment, the thickness of the second molding region 500b and the thickness of the first molding region 500a may be formed to be the same. A top surface of the second molding region 500b may be the top surface of the molding layer 500. Furthermore, the bottom surface of the second molding region 500b may be a top surface of the third molding region 500c. In other words, the second molding region 500b may be a region from the top surface of the third molding region 500c to the top surface of the molding layer 500. However, it is not limited thereto, and the bottom surface of the second molding region 500b may be spaced apart from the top surface of the third molding region 500c.

The density of the wavelength converting particles 400 in the second molding region 500b may be formed to be less than the density of the wavelength converting particles 400 in the first molding region 500a. The density of the wavelength converting particles 400 of the second molding region 500b may be calculated by the number of wavelength converting particles 400 disposed on a second cross-section or the area of the wavelength converting particles 400 relative to a total area of the second cross-section, when the second cross-section of the second molding region 500b is formed by cutting the second molding region 500b in a direction passing through cross-sections of at least two of the plurality of light emitters 200 arranged in one direction and perpendicular to the substrate 100. The density of the wavelength converting particles 400 of the second molding region 500b may be 10% to 20% of the total area of the second cross-section.

The third molding region 500c may be disposed between the plurality of light emitters 200 and may be disposed below the second molding region 500b. An upper side of the third molding region 500c may be disposed in a region corresponding to one-third of a height of the light emitter 200. The upper side of the third molding region 500c may be disposed lower than a top surface of the transmissive layer 240. The upper side of the third molding region 500c may be in contact with a lower side of the second molding region 500b. Furthermore, a bottom surface of the third molding region 500c may be disposed on a top surface of the electrode pad 300. In other words, the third molding region 500c may be a region from the top surface of the electrode pad 300 to the bottom surface of the second molding region 500b. However, it is not limited thereto, and the upper side of the third molding region 500c and the lower side of the second molding region 500b may be spaced apart from each other.

A thickness of the third molding region 500c may be the same as the thickness of the first molding region 500a. The density of the wavelength converting particles 400 in the third molding region 500c may be less than the density of the wavelength converting particles 400 in the first molding region 500a. Through the wavelength converting particles 400 of the third molding region 500c, chromatic aberration may be reduced by increasing the excitation efficiency of light emitted toward the top surface of the light emitter 200 more than the excitation efficiency of light emitted toward the side surface of the light emitter 200. The density of the wavelength converting particles 400 of the third molding region 500c may be calculated by the number of wavelength converting particles 400 disposed on a third cross-section or the area of the wavelength converting particles 400 relative to a total area of the third cross-section, when the third cross-section of the third molding region 500c is formed by cutting the third molding region 500c in a direction passing through cross-sections of at least two of the plurality of light emitters 200 arranged in one direction and perpendicular to the substrate 100. The density of the wavelength converting particles 400 of the third molding region 500c may be 10% to 20% of the total area of the third cross-section.

Furthermore, the density of the wavelength converting particles 400 in the third molding region 500c may be equal to or less than the density of the wavelength converting particles 400 in the second molding region 500b. Through the wavelength converting particles 400 in the third molding region 500c, chromatic aberration may be reduced by adjusting the excitation efficiency of light emitted toward the side surface of the light emitter 200.

The fourth molding region 500d may be a region enclosed by a virtual line extending from an outer side of the electrode pad 300 to an edge of a top surface of the light emitter 200, a side surface of the light emitter 200, and a top surface of the electrode pad 300. In one embodiment, the fourth molding region 500d may be a region formed by a first virtual line connecting one side of the top surface of the light emitter 200 and an outer side of the first electrode pad 310, the top surface of the first electrode pad 310, and one side surface of the light emitter 200. In another embodiment, the fourth molding region 500d may be a region formed by a virtual second virtual line connecting another side opposite to the one side of the top surface of the light emitter 200 and an outer side of the second electrode pad 320, the top surface of the second electrode pad 320, and another side surface opposite to the one side surface of the light emitter 200. At least a part of the fourth molding region 500d may overlap with the third molding region 500c.

The density of the wavelength converting particles 400 in the fourth molding region 500d may be formed to be greater than the density of the wavelength converting particles 400 in at least one of the second molding region 500b and the third molding region 500c. Through the wavelength converting particles 400 in the fourth molding region 500d, chromatic aberration may be improved by adjusting the excitation efficiency of light emitted to a side region close to the light emitter 200. The density of the wavelength converting particles 400 of the fourth molding region 500d may be calculated by the number of wavelength converting particles 400 disposed on a fourth cross-section or the area of the wavelength converting particles 400 relative to a total area of the fourth cross-section, when the fourth cross-section of the fourth molding region 500d is formed by cutting the fourth molding region 500d in a direction passing through cross-sections of at least two of the plurality of light emitters 200 arranged in one direction and perpendicular to the substrate 100. The density of the wavelength converting particles 400 of the fourth molding region 500d may be 10% to 20% of the total area of the fourth cross-section.

Hereinafter, operations and effects of the light emitting device 10 and the light emitting system 1 including the same according to the first embodiment of the present disclosure will be described.

Light generated from the light emitter 200 of the light emitting device 10 according to the first embodiment of the present disclosure may be absorbed by the wavelength converting particles 400. The wavelength converting particles 400 may emit the absorbed light as light of a different wavelength. The light emitted from the wavelength converting particles 400 may be transmitted through the molding layer 500 and emitted to the outside.

Since the density of the wavelength converting particles 400 in the region directly over the light emitter 200 of the molding layer 500 of the light emitting device 10 may be formed to be greater than the density in other regions of the molding layer 500, the wavelength of the light generated from the light emitter 200 may be efficiently converted.

Furthermore, since the density of the wavelength converting particles 400 in the region directly over the light emitter 200 may be formed to be greater than the density in other regions of the molding layer 500, a contrast ratio and contrast of the light emitted from the wavelength converting particles 400 may be increased.

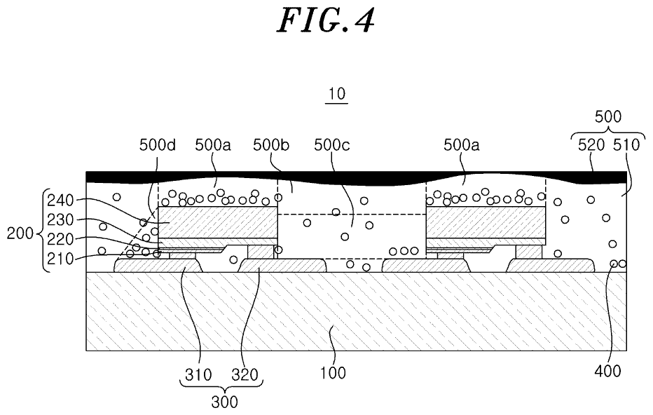

Hereinafter, a light emitting device 10 according to a second embodiment of the present disclosure will be described with reference to FIG. 4. In describing the second embodiment, the difference is that the molding layer 500 includes a first molding layer 510 and a second molding layer 520, and the description will focus on this difference.

The wavelength converting particles 400 may be disposed in at least one of the first molding layer 510 and the second molding layer 520.

The first molding layer 510 may be disposed on the substrate 100 to cover the plurality of light emitters 200 and the plurality of electrode pads 300. A region of the first molding layer 510 disposed directly above the plurality of light emitters 200 may be included in the first molding region 500a. A region of the first molding layer 510 disposed between the plurality of first molding regions 500a may be included in the second molding region 500b. A region of the first molding layer 510 disposed below the second molding region 500b may be included in the third molding region 500c. Furthermore, at least a portion of a region of the first molding layer 510 disposed on a side surface of the light emitter 200 may be included in the fourth molding region 500d.

A thickness of the first molding layer 510 may be formed to be greater than a thickness of the second molding layer 520. At least a portion of a top surface of the first molding layer 510 may be formed to be convex upward. In other words, the top surface of the first molding layer 510 located in the first molding region 500a may be formed to be convex upward. A distance between the top surface of the first molding layer 510 and a top surface of the second molding layer 520 in the first molding region 500a may be smaller than a distance between the top surface of the first molding layer 510 and the top surface of the second molding layer 520 in the second molding region 500b. Through the first molding layer 510, a light path may be adjusted.

The second molding layer 520 may be stacked on the first molding layer 510. The second molding layer 520 may have a lower light transmittance than the first molding layer 510. Furthermore, the second molding layer 520 may also absorb light. A color of the second molding layer 520 may be black. A region of the second molding layer 520 disposed directly above the plurality of light emitters 200 may be included in the first molding region 500a. A region of the second molding layer 520 disposed between the plurality of first molding regions 500a may be included in the second molding region 500b. A thickness of the second molding layer 520 in the first molding region 500a may be smaller than a thickness of the second molding layer 520 in the second molding region 500b. Through the first molding region 500a, a decrease in the amount of light may be reduced while increasing contrast.

A bottom surface of the second molding layer 520 may be disposed higher than a lower side of the first molding region 500a. At least a part of the bottom surface of the second molding layer 520 in the second molding region 500b may be formed to be convex downward. Due to the bottom surface of the second molding layer 520, light emitted between the light emitters 200 is adjusted, so that color purity may be increased.

A light transmittance of light passing through the second molding layer 520 included in the first molding region 500a may be greater than a light transmittance of light passing through the second molding layer 520 included in the second molding region 500b. Due to the transmittance, a decrease in the amount of light may be reduced while increasing contrast.

Hereinafter, operations and effects of the light emitting device 10 according to the second embodiment of the present disclosure will be described.

Light emitted from the wavelength converting particles 400 of the light emitting device 10 according to the second embodiment of the present disclosure may sequentially pass through the first molding layer 510 and the second molding layer 520.

By the molding layer 500, a light transmittance in the first molding region 500a may be formed to be greater than a light transmittance in the second molding region 500b, and thus, a contrast ratio and contrast of the light emitting device 10 may be increased.

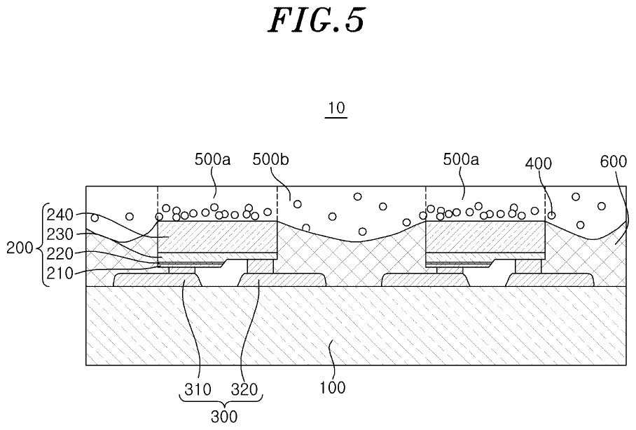

Hereinafter, a light emitting device 10 according to a third embodiment of the present disclosure will be described with reference to FIG. 5. In describing the third embodiment, the difference is that the light emitting device 10 further includes a reflective layer 600, and the description will focus on this difference.

The reflective layer 600 is disposed on the substrate 100 at a side of the plurality of light emitters 200, and may reflect light directed sideways from the plurality of light emitters 200 toward the plurality of light emitters 200. In one embodiment, the reflective layer 600 may be disposed between the plurality of light emitters 200. Furthermore, a plurality of reflective layers 600 may be formed and disposed on an outer side of the plurality of light emitters 200. Light may be reflected from a side of the reflective layer 600. Therefore, inside the reflective layer 600, light extraction efficiency is increased, and on an upper side, light may be absorbed, so that contrast may be increased. A top surface of the reflective layer 600 may be bent downward between the plurality of light emitters 200 so as to be disposed lower than a bottom surface of the plurality of light emitters 200. The reflective layer 600 may be formed such that the thickness thereof decreases toward the center. The thickness of the reflective layer 600 may increase from the center toward the light emitter 200.

Furthermore, the reflective layer 600 may be disposed to be in contact with a side surface of at least one of the plurality of light emitters 200 to reflect light toward the at least one of the plurality of light emitters 200. For example, a color of the reflective layer 600 may be white. A reflectance of the reflective layer 600 may be formed to be greater than a reflectance of the transmissive layer 240. Light reflected from the reflective layer 600 may be transmitted through the light emitter 200. The reflective layer 600 may include acrylic, silicone, epoxy series, a filler for increasing reflectivity, and the like. The filler may include at least one of TiO₂, Al₂O, and SiO₂. Furthermore, the filler may include a high-reflection polymer (PTFE, PMMA), magnesium oxide (MgO), and the like. Furthermore, the reflective layer 600 may include a hollow filler containing an air layer inside the filler to increase light extraction efficiency by diversifying the path of side light. When the hollow filler is included, a density of the reflective layer 600 may become lower than a density of other regions. Furthermore, the reflective layer 600 may include carbon.

Furthermore, the reflective layer 600 may be formed such that a color of the reflective layer 600 when viewed from above and a color of the reflective layer 600 when viewed from a side are different. A brightness of the reflective layer 600 when viewed from above may be lower than a brightness thereof when viewed from the side. The color of the reflective layer 600 when viewed from above may be black. Light may be absorbed at an upper side of the reflective layer 600. Furthermore, the color of the reflective layer 600 when viewed from the side may be transparent or white. Through the reflective layer 600, both light extraction efficiency and contrast may be improved.

Hereinafter, operations and effects of the light emitting device 10 according to the third embodiment of the present disclosure will be described.

Light generated from the plurality of light emitters 200 according to the third embodiment of the present disclosure may be directed upward or sideways. The reflective layer 600 is disposed at a side of the plurality of light emitters 200 and may reflect light directed sideways from the light emitter 200 toward the light emitter 200. The light reflected from the reflective layer 600 may be transmitted through the light emitter 200 and may have its wavelength changed by the wavelength converting particles 400 while being transmitted through the molding layer 500.

By the reflective layer 600, optical interference between the plurality of light emitters 200 may be reduced, so that a distinct contrast ratio and contrast may be formed.

Furthermore, since the reflective layer 600 may reflect light toward the light emitter 200, the light extraction efficiency may be increased.

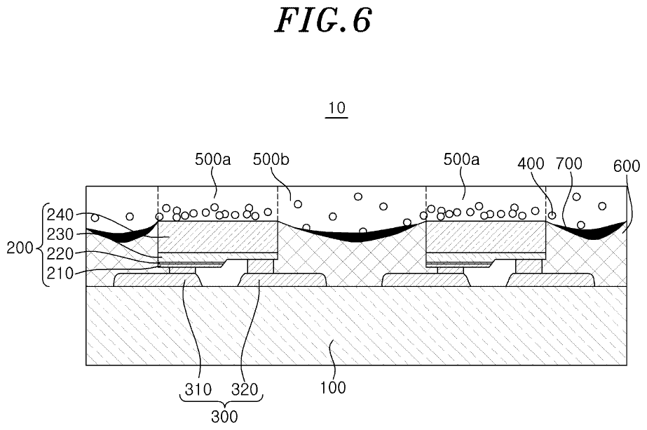

Hereinafter, a light emitting device 10 according to a fourth embodiment of the present disclosure will be described with reference to FIG. 6. In describing the fourth embodiment, the difference is that the light emitting device 10 further includes a light absorbing layer 700, and the description will focus on this difference.

The light absorbing layer 700 may absorb light. The light absorbing layer 700 may be disposed on an upper side of the reflective layer 600 to cover the reflective layer 600. A thickness of the light absorbing layer 700 may be formed to be smaller than a thickness of the reflective layer 600. In other words, an area of a side surface of the light emitter 200 in contact with the reflective layer 600 may be formed to be greater than an area of the side surface of the light emitter 200 in contact with the light absorbing layer 700. The light absorbing layer 700 may extend along a shape of a top surface of the reflective layer 600.

The light absorbing layer 700 may prevent the reflective layer 600 from being exposed when viewed from above. A color of the light absorbing layer 700 may be black. In one embodiment, the light absorbing layer 700 may be stacked on the reflective layer 600. In other words, the light absorbing layer 700 and the reflective layer 600 may be separated into separate layers. Therefore, light may be refracted by an interface between the light absorbing layer 700 and the reflective layer 600, so that an amount of light re-entering the reflective layer 600 may be increased, and emission of light to the outside through the reflective layer 600 may be prevented. In another embodiment, the light absorbing layer 700 and the reflective layer 600 may be integrally formed. Therefore, a bonding force between the light absorbing layer 700 and the reflective layer 600 may be increased.

Furthermore, the light absorbing layer 700 may include carbon. A carbon content of the reflective layer 600 may be smaller than a carbon content of the light absorbing layer 700. Alternatively, a weight percentage (wt %) of carbon in the reflective layer 600 may be smaller than a weight percentage (wt %) of carbon in the light absorbing layer 700. Alternatively, an atomic percentage (at %) of carbon in the reflective layer 600 may be smaller than an atomic percentage (at %) of carbon in the light absorbing layer 700. Therefore, a difference in transmittance and reflectance between the light absorbing layer 700 and the reflective layer 600 may be large. Accordingly, design difficulty may be lowered by easily adjusting reflection and absorption for each region.

Hereinafter, operations and effects of the light emitting device 10 according to the fourth embodiment of the present disclosure will be described.

Since light may be absorbed by the light absorbing layer 700, mixing of light between adjacent light emitters 200 may be prevented, and color distinction between the light emitters 200 may become more distinct.

The examples of the present disclosure have been described above as specific embodiments, but these are only examples, and the present disclosure is not limited thereto, and should be construed as having the widest scope according to the technical spirit disclosed in the present specification. A person skilled in the art may combine/substitute the disclosed embodiments to implement a pattern of a shape that is not disclosed, but it also does not depart from the scope of the present disclosure. In addition, those skilled in the art can easily change or modify the disclosed embodiments based on the present specification, and it is clear that such changes or modifications also belong to the scope of the present disclosure.

### DESCRIPTION OF REFERENCE NUMERALS

1: Light Emitting Device
100: Substrate
200: light emitter
210: first conductive type semiconductor layer
220: active layer
230: second conductive type semiconductor layer
240: transparent layer
300: electrode pad
310: first electrode pad
320: second electrode pad
400: wavelength conversion particles
500: molding layer
500a: first molding region
500b: second molding region
500c: third molding region
500d: fourth molding region
510: first molding layer
520: second molding layer
600: reflective layer
700: light absorbing layer

1. A light emitting device, comprising:
a substrate;
a light emitter disposed on the substrate to generate light;
a molding layer disposed on the substrate to cover the light emitter; and
a plurality of wavelength converting particles disposed in the molding layer,
wherein the molding layer includes:
a first molding region disposed directly above the light emitter; and
a second molding region disposed laterally adjacent to the light emitter, and
wherein a density of the wavelength converting particles in the first molding region is greater than a density of the wavelength converting particles in the second molding region.

2. The light emitting device of claim 1, wherein the first molding region is a region from a top surface of the light emitter to a top surface of the molding layer.

3. The light emitting device of claim 1, wherein the light emitter and the first molding region are formed in plurality and are arranged spaced apart from each other in one direction, and
wherein the second molding region is disposed between the plurality of first molding regions.

4. The light emitting device of claim 3, wherein the second molding region is disposed such that a surface of the molding layer is disposed on a top surface of the second molding region, and
wherein the first molding region and the second molding region have the same thickness.

5. The light emitting device of claim 3, wherein when a cross-section is formed by cutting the molding layer in a direction passing through the plurality of light emitters arranged in the one direction and perpendicular to the substrate, the density of the wavelength converting particles is calculated by a number of the wavelength converting particles disposed on the cross-section or an area of the wavelength converting particles on the cross-section.

6. The light emitting device of claim 1, wherein the first molding region is disposed to be in contact with a top surface of the light emitter and a top surface of the molding layer, and a thickness of the second molding region is greater than a thickness of the first molding region.

7. The light emitting device of claim 1, wherein the second molding region is disposed such that a surface of the molding layer is disposed on a top surface of the second molding region,
wherein the molding layer further includes a third molding region disposed below the second molding region, and
wherein a density of the wavelength converting particles in the third molding region is less than the density of the wavelength converting particles in the first molding region.

8. The light emitting device of claim 7, wherein a thickness of the third molding region is the same as a thickness of the first molding region.

9. The light emitting device of claim 1, further comprising:
an electrode pad disposed between the substrate and the light emitter, electrically connected to the light emitter, and covered by the molding layer,
wherein an outer side of the electrode pad is disposed outward of a side surface of the light emitter,
wherein the molding layer includes a fourth molding region enclosed by a virtual line extending from the outer side of the electrode pad to an edge of a top surface of the light emitter, a side surface of the light emitter, and a top surface of the electrode pad, and
wherein a density of the wavelength converting particles in the fourth molding region is greater than the density of the wavelength converting particles in the second molding region.

10. A light emitting device, comprising:
a substrate;
a plurality of light emitters disposed on the substrate to generate light;
a molding layer disposed on the substrate to cover the plurality of light emitters; and
a plurality of wavelength converting particles disposed in the molding layer,
wherein the molding layer includes:
a first molding layer covering the plurality of light emitters and transmitting light generated from the plurality of light emitters; and
a second molding layer stacked on the first molding layer and having a lower light transmittance than the first molding layer, and
wherein the wavelength converting particles are disposed in at least one of the first molding layer and the second molding layer.

11. The light emitting device of claim 10, wherein the molding layer includes:
a first molding region disposed directly above the plurality of light emitters; and
a second molding region disposed laterally adjacent to the plurality of light emitters,
wherein a portion of the first molding layer and a portion of the second molding layer are disposed in the first molding region,
wherein another portion of the first molding layer and another portion of the second molding layer are disposed in the second molding region, and
wherein a density of the wavelength converting particles in the first molding region is greater than a density of the wavelength converting particles in the second molding region.

12. The light emitting device of claim 11, wherein the first molding layer included in the first molding region is formed to be convex upward.

13. The light emitting device of claim 11, wherein a thickness of the portion of the second molding layer in the first molding region is smaller than a thickness of the another portion of the second molding layer in the second molding region.

14. The light emitting device of claim 11, wherein a light transmittance in the second molding layer disposed in the first molding region is greater than a light transmittance in the second molding layer disposed in the second molding region.

15. The light emitting device of claim 10, wherein a thickness of the first molding layer is greater than a thickness of the second molding layer.

16. A light emitting device, comprising:
a substrate;
a light emitter disposed on the substrate to generate light;
a reflective layer disposed on the substrate and positioned laterally of the light emitter to reflect light toward the light emitter;
a molding layer covering an upper side of the reflective layer and the light emitter; and
a plurality of wavelength converting particles disposed in the molding layer,
wherein the molding layer includes:
a first molding region disposed directly above the light emitter; and
a second molding region disposed directly above the reflective layer, and
wherein a density of the wavelength converting particles in the first molding region is greater than a density of the wavelength converting particles in the second molding region.

17. The light emitting device of claim 16, wherein the reflective layer comprises:
a reflective region disposed laterally of the light emitter to reflect light toward the light emitter; and
a light absorbing layer covering the reflective region and disposed below the molding layer to absorb light.

18. The light emitting device of claim 17, wherein a thickness of the reflective region is greater than a thickness of the light absorbing layer.

19. The light emitting device of claim 17, wherein a reflectance of the reflective region is greater than a reflectance of the molding layer.

20. The light emitting device of claim 16, wherein the light emitter includes a plurality of light emitters, and
wherein a bottom surface of the molding layer is bent downward between the plurality of light emitters so as to be disposed lower than an upper end of the plurality of light emitters.
